(19) United States
(12) Patent Application Publication
(10) Pub. No.: US 2008/0078576 A1
(43) Pub. Date: Apr. 3, 2008

(54) Carbon Foam EMI Shield

(75) Inventors: Jesse M. Blacker, Bridgeport, OH (US); Douglas J. Merriman, Wheeling, WV (US)

Correspondence Address: PHILIP D. LANE, P.O. BOX 79318, CHARLOTTE, NC, 28271-7063, US

(73) Assignee: TOUCHSTONE RESEARCH LABORATORY, LTD., Triadelphia, WV (US)

(21) Appl. No.: 11/757,992

(22) Filed: Jun. 4, 2007

Related U.S. Application Data
(60) Provisional application No. 60/803,847, filed on Jun. 2, 2006.

(51) Int. Cl. H05K 9/00

(52) U.S. Cl. 174/388

(57) ABSTRACT

An EMI shield having an EMI shielding effectiveness of greater than about 40 dB in the range of about 400 MHz to about 18 GHz is described. In some embodiments the EMI shield may exhibit a shielding effectiveness of at least about 60 db, and in other embodiment at least about 80 dB, in the range of about 400 MHz to about 8 GHz. The EMI shield may include at least two sections of rigid porous electrically conductive carbon joined together by an electrically conductive carbon containing adhesive. The rigid porous electrically conductive carbon may include electrically conductive carbon foam. The electrically conductive carbon containing adhesive may include electrically conductive carbon fibers in a polymer matrix.

### BRIEF SUMMARY OF THE INVENTION

The present invention may include a carbon foam EMI shield that has an EMI shielding effectiveness of at least about 40 dB in the range of about 400 MHz to about 18 GHz. In certain embodiments, the carbon foam EMI shield may have a shielding effectiveness of at least about 60 dB in the range of about 400 MHz to about 8 GHz. In some embodiments, the carbon foam EMI shield may have an EMI shielding effectiveness of greater than about 80 dB in the range of about 400 MHz to about 8 GHz. Some embodiments may include at least two sections of rigid porous electrically conductive carbon joined by an electrically conductive carbon containing adhesive to form an EMI shield, wherein said EMI shield has a shielding effectiveness of at least 40 dB between about 400 MHz and about 18 GHz. In some embodiments, the rigid porous electrically conductive carbon may include carbon foam. The electrically conductive carbon containing adhesive may comprise from about 5% to about 20% by weight electrically conductive carbon fibers in a polymer matrix.

Other embodiments may include an EMI shield comprising at least two sections of electrically conductive carbon foam joined by an electrically conductive carbon containing adhesive to form an EMI shield. The electrically conductive carbon containing adhesive may comprise from about 10% to about 15% by weight electrically conductive carbon fibers in a polymer matrix. The electrically conductive carbon fibers may have a diameter ranging from about 100 mm to about 200 nm and lengths ranging from about 30,000 nm to about 100,000 nm. The EMI shield may a shielding effectiveness of at least 80 dB between about 400 MHz and about 8 GHz.

### BRIEF DESCRIPTION OF THE DRAWINGS

FIG. 1 illustrates an EMI shield in accordance with an embodiment of the invention.

FIG. 2 illustrates an EMI shield in accordance with another embodiment of the invention.

FIG. 3 illustrates an EMI shield in accordance with a further embodiment of the invention.

FIG. 4 illustrates an EMI shield in accordance with a further embodiment of the invention.

FIG. 5 illustrates an EMI shield in accordance with a further embodiment of the invention.

FIG. 6 is a plot of EMI shielding effectiveness for Example 1. Data for an aluminum plate is indicated by a dashed line. Data for the EMI shield for Example 1 is indicated by a solid line.

FIG. 7 is a plot of EMI shielding effectiveness for Example 2. Data for an aluminum plate is indicated by a dashed line. Data for the EMI shield for Example 2 is indicated by a solid line.

FIG. 8 is a plot of EMI shielding effectiveness for Example 3. Data for an aluminum plate is indicated by a dashed line. Data for the EMI shield for Example 3 is indicated by a solid line.

FIG. 9 is a plot of EMI shielding effectiveness for Example 4. Data for an aluminum plate is indicated by a dashed line. Data for the EMI shield for Example 4 is indicated by a solid line.

### DETAILED DESCRIPTION OF EMBODIMENTS OF THE INVENTION

Electrically conductive carbon foams are effective in blocking high frequency electromagnetic interference (EMI) such as that generated by microwave emitters, including radar sources. Typically, such electrically conductive carbon foams have an electrical resistivity of less than about 1 ohm-cm and in some instances less than about 0.1 ohm-cm. Such electrically conductive carbon foams may be used on structures such as walls, enclosures, or shelters, to shield an interior volume from EMI. The interior volumes of these enclosures provide areas in which personnel, electronic equipment, and/or items and materials may be sheltered and function without the negative effects that may result from exposure to such interference. Additionally, due to the inherent strength of carbon foam, the carbon foam may be used to form such structures. Further, other embodiments may include rigid porous electrically conductive carbon.

The electrically conductive carbon foam is typically arranged such that the carbon foam provides for an essentially continuous surface within or over the walls of the structure. Breaks, separations, cracks, or the like, in this essentially continuous electrically conductive carbon foam surface may significantly degrade the EMI shielding effectiveness of the structure.

Carbon foam is commercially available in sheet form. The construction of structures from sheets of carbon foam requires that these sheets be pieced together in appropriate configurations. Neighboring sheets or pieces of electrically conductive carbon foam have gaps, seams, or cracks along their respective joining lines. These joining lines, unless sealed may significantly degrade the EMI shielding effectiveness of the structure. To seal these gaps, seams, or cracks, the carbon foam pieces are bonded to each other over the joining line using selected electrically conductive adhesives. The use of such electrically conductive adhesives reduces breaks, separations, cracks, loss of electrical conductivity, or the like, between neighboring electrically conductive carbon foam sections. In this manner a continuous electrically conductive enclosure surface may be obtained.

The use of electrically conductive adhesives for the bonding of neighboring carbon foam sheets or pieces (which may be referred to collectively as carbon foam sections), does not invariably result in a bond that exhibits the desired shielding effectiveness. Although electrically conductive, many of the commercially available electrically conductive adhesives may not adequately, or reliably, block high frequency EMI. This inadequate EMI blocking may result in some joining lines between electrically conductive carbon foam sections having the appearance of breaks, separations, cracks, or the like, with respect to the shielding effectiveness of the enclosure. That is, the adhesive bonding between the carbon foam sections may provide pathways for entry, (i.e. “leakage”) of EMI into the enclosure interior, thus degrading the shielding effectiveness of the enclosure.

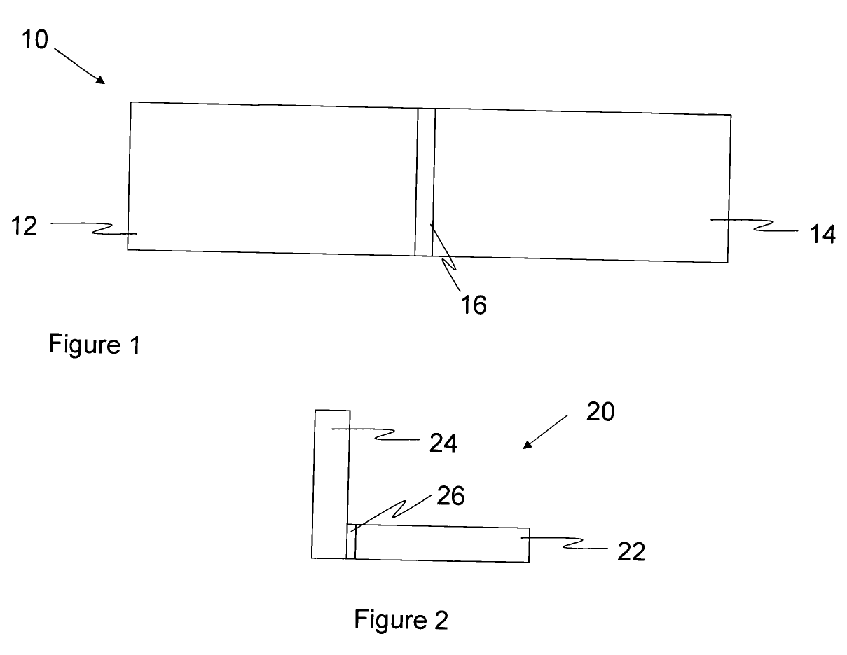

With reference now to FIG. 1, an EMI shield 10 in accordance with an embodiment of the invention is illustrated. At least two electrically conductive carbon foam sections 12 and 14 are joined together by an electrically conductive carbon containing adhesive 16. In various embodiments, the electrically conductive carbon containing adhesive 16 and the carbon foam sections 12 and 14 exhibit substantially electrically continuous communication between the carbon foam sections 12 and 14 and the electrically conductive carbon containing adhesive 16.

The carbon foam sections may be any electrically conductive carbon foam. Carbon foam is an open-celled carbonaceous material. While the size of the cells throughout the carbon foam will vary, the distribution of the cell sizes throughout the carbon foam is relatively uniform. In some embodiments, the carbon foam may exhibit a bimodal distribution of cell sizes. Carbon foams may exhibit densities ranging from about 0.05 g/cc to about 1.2 g/cc. In some embodiments, carbon foam may exhibit densities ranging from about 0.1 g/cc to about 1.0 g/cc. Further carbon foams may exhibit compressive strengths ranging from about 50 p.s.i. to about 12,000 p.s.i. In various embodiments, the carbon foam may exhibit compressive strengths ranging from about 150 p.s.i. to about 10,000 p.s.i. The carbon foam may exhibit an electrical resistivity less than about 1 ohm-cm. In other embodiments, the carbon foam may exhibit an electrical resistivity of less than about 0.1 ohm-cm.

Carbon foams may be produced using a variety of feedstocks known to those skilled in the art. Carbon foam may be any produced, for example, from pitches, mesophase carbon, mesophase pitches, coal, coal extracts, coal derivatives. Further, carbon foam may also be produced by carbonizing polymeric foams. Such polymeric foams may include, but are not limited to, phenolic foams and resorcinol foams. Other types of polymeric foams may include, but are not limited to, those polymeric foams made from vinylidene chloride, furfuryl alcohol, furan resins, polyacrylonitrile, polyurethane, combinations thereof, or the like. In certain embodiments the carbon foam may be carbon foam that is graphitized or has been heated to graphitization temperatures, typically above about 3,000° C.

The electrically conductive carbon containing adhesive is an adhesive that provides electrical communication between the carbon foam sections. The electrically conductive carbon containing adhesive should not significantly corrode or galvanize the carbon foam. The electrically conductive carbon containing adhesive bonds the carbon foam sections together a provides an EMI shield with a shielding effectiveness of at least about 40 dB in the range of about 400 MHz to about 18 GHz. In certain embodiments at least about 60 dB, or even at least about 80 dB in the range of about 400 MHz to about 8 GHz. In some embodiments, a shielding effectiveness of at least 85 dB, and in certain embodiment at least 90 dB, is provided in the range of about 400 MHz to about 8 GHz.

In certain embodiments, the electrically conductive carbon containing adhesive may comprise from about 1% to about 75% by weight electrically conductive carbon in a polymer matrix. Some embodiments may include from about 5% to about 60% by weight, and in other embodiments from about 5 to about 20% by weight electrically conductive carbon in a polymer matrix. In still other embodiments, the electrically conductive carbon containing adhesive may comprise from about 10 to about 15% by weight electrically conductive carbon in a polymeric matrix. In still other embodiments, the electrically conductive carbon containing adhesive may comprise about 12% by weight electrically conductive carbon in a polymeric matrix. The electrically conductive carbon may include carbon particles, graphite particles, carbon fibers, and other similar electrically conductive carbon materials. The electrically conductive carbon should be nearly as conductive as the rigid porous electrically conductive carbon of the adjoining panels or sections. The size of the electrically conductive carbon for the adhesive is not particularly limited. The size of the electrically conductive carbon should be sufficiently small so as to be supported or suspended in the polymer matrix.

Carbon fibers may be utilized as the electrically conductive carbon for the adhesive. The electrically conductive carbon fibers may have a diameter ranging from about 100 nm to about 200 nm and lengths ranging from about 30,000 nm to about 100,000 nm. In some embodiments, the electrically conductive carbon fibers may be surface coated with carbon that has been graphitized. In some embodiments, electrically conductive carbon fibers may include, but are not limited to Pyrograf® III carbon fibers, such as PR-19 and PR-24, commercially available from Pyrograf Products Inc.

The polymer matrix of the electrically conductive carbon containing adhesive is not particularly limited and may include any polymeric materials that when cured adhesively bond to carbon foam and do not significantly degrade the carbon foam or carbon fibers. The polymeric matrix may include, but is not limited to, epoxy, polyurethane, polyacrylonitrile, polyesters, phenolic resin, vinyl esters resins [look up], resorcinol resins, furan resins, or other similar materials. In some embodiments, the polymeric matrix may be cured at about room temperature.

The electrically conductive carbon foam sections may be joined together in virtually any configuration. The electrically conductive carbon foam sections may be joined together to form a larger planar EMI shield as illustrated in FIG. 1. Alternatively, two or more electrically conductive carbon foam sections may be joined together at various angles to provide differing shapes and configurations for the EMI shield. With reference to FIG. 2, an embodiment of an EMI shield 20 is illustrated in which at least two electrically conductive carbon foam sections 22 and 24 are joined together with an electrically conductive carbon containing adhesive 26 at an angle less than 180° C. The embodiment shown in FIG. 2 shows the electrically conductive carbon foam section 22 and 24 joined at an angle of about 90°. The conductive carbon containing adhesive 26 has the same properties as the electrically conductive carbon containing adhesive discussed above.

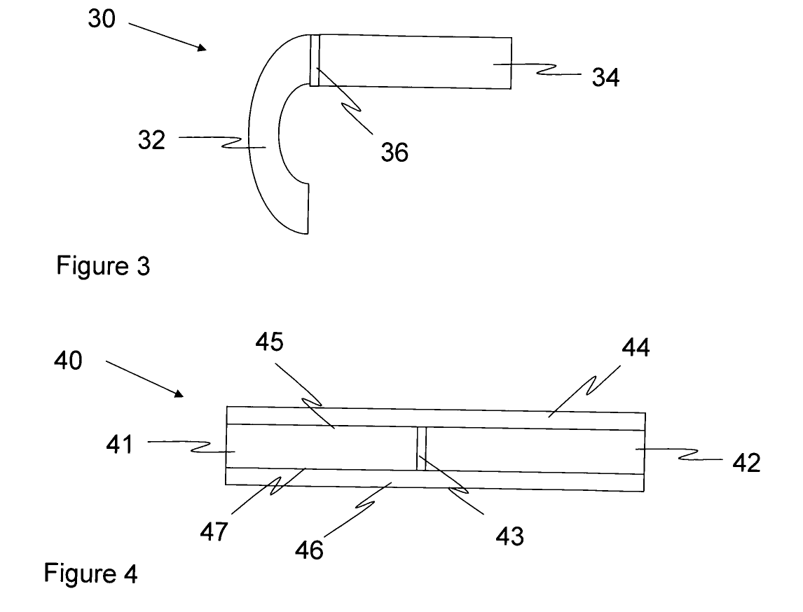

The carbon foam EMI shield may also contain curved carbon foam sections. With reference to FIG. 3, an embodiment of a carbon foam EMI shield 30 is illustrated in which a curved section of electrically conductive carbon foam 32 is joined with a relatively planar section of electrically conductive carbon foam 34 by an electrically conductive carbon containing adhesive 36. The conductive carbon containing adhesive 36 has the same properties as the electrically conductive carbon containing adhesive discussed above.

The electrically conductive carbon foam sections may be joined by any variety of common joining techniques. For example, the electrically conductive sections may be joined together using joints that include, but are not limited to, butt joints, lap joints, half lap joints, dove tail joints, mortis and tenon joints, tongue and groove joints, V-groove joint, and other similar joining techniques commonly known in the carpentry arts. As will be discussed below, the electrically conductive carbon containing adhesive would be applied to the surfaces of the electrically carbon foam sections making up the particular joint.

The carbon foam EMI shield may include one or more laminating layers on one or more surfaces of the carbon foam sections joined together by the electrically conductive carbon containing adhesive. As shown in FIG. 4, an embodiment of a carbon foam EMI shield 40 is illustrated. The carbon foam EMI shield 40 includes two or more sections of carbon foam 41 and 42 joined together with an electrically conductive carbon containing adhesive 43. A first laminating layer 44 is positioned on a first surface 45 of the two or more sections of carbon foam 41 and 42 and another layer 46 is positioned on a second surface 47 of the two or more sections of carbon foam 41 and 42. Additional laminating layers may be provided if desired. Laminating materials may provide, for example, additional wall strength, bracing at wall intersections, waterproofing, weather shielding, impact resistance, and the like. The materials for the laminating layers are not particularly limited, except that laminating layers contacting the surfaces of the carbon foam sections should not significantly degrade the carbon foam. Laminating materials may include but are not limited to, wood, balsa wood, fiberglass, carbon fibers, plastic or polymeric sheets or layers, carbon foam, thermosetting and thermoplastic polymers, ceramics, paint, polymer composites, carbon composites, paper, metals, and/or metal composites. An adhesive suitable for joining the laminating material to the carbon foam may be used. Metals may be used as laminating layers but care should be taken when they are used adjacent to the carbon foam sections to prevent galvanization or corrosion. In some embodiments an intermediate layer would be used between the metal laminating layer and the carbon foam sections. In some embodiments stainless steel may be used adjacent to the carbon foam section without significant galvanization or corrosion.

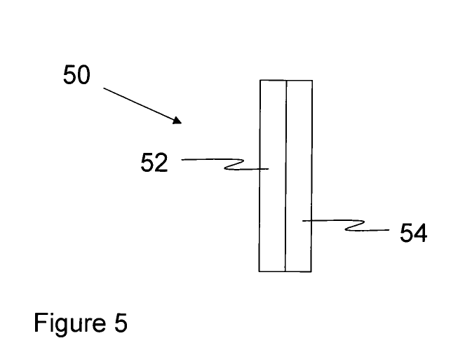

The carbon foam EMI shield may be used in any of a wide variety of situations. In some embodiments, the carbon foam EMI shield may be positioned or affixed to a wall. The wall may be any wall of a structure or enclosure which will be exposed to EMI. With reference to FIG. 5, there is shown a carbon foam EMI shield 50 positioned on the surface 52 of a wall 54. The carbon foam EMI shield 50 may be affixed to the surface 52 by any variety of techniques. Care should be taken not to form cracks, gaps, or other similar defects or breaches in the carbon foam EMI shield as any such defect will likely degrade the shielding effectiveness of the carbon foam EMI shield. In various embodiments the carbon foam EMI shield is adhered to the surface by a suitable adhesive. The adhesive will vary depending upon such factors as the material of the surface 52 and the material of any laminating layers present with the carbon foam EMI shield. In certain embodiments, the carbon foam EMI shield is sized to cover the entire surface of the wall.

Certain carbon foam sections exhibit relatively high compressive strengths, up to about 12,000 p.s.i. This feature of carbon foam allows for carbon foam sections to be used in forming the walls of the structure or enclosure. While all of the carbon foams may be used to form walls of a structure or enclosure, the strength of the enclosure will generally increase as the compressive strength of the carbon foam sections increases. Using laminating layers on surfaces of the carbon foam sections may provide the structure or enclosure with increased strength and/or durability.

Having described various embodiments of a carbon foam EMI enclosure, methods for producing carbon foam EMI enclosures will be described. Electrically conductive carbon foam sections are sized and shaped for the particular desired configuration of the resulting carbon foam EMI enclosure. Each joining edge of the carbon foam sections is shaped to correspond to the joining technique to be used. For example, if a tongue and groove technique is going to be used, one joining edge is shaped with the tongue and the opposing joining edge is shaped with the corresponding mating groove. The electrically conductive carbon containing adhesive having the characteristics described above is applied on all joining surfaces of the carbon foam sections. The electrically conductive carbon containing adhesive should be applied such that gaps do not exist between neighboring carbon foam sections. As discussed above, gaps, cracks, and other similar defects reduce the EMI shielding effectiveness of the carbon foam EMI shield.

The electrically conductive carbon containing adhesive is allowed to cure. In certain embodiments, the electrically conductive carbon containing adhesive is one that cures near ambient temperature. If the electrically conductive carbon containing adhesive requires elevated temperatures for curing, the carbon foam sections joined with the adhesive is brought up to a temperature sufficient to curing the adhesive. Depending upon the curing temperature, the heating rate to the curing temperature should be slow enough to avoid significant thermal gradients that may result in the cracking of the carbon foam sections, cracking of the electrically conductive carbon containing adhesive, or separation between the electrically conductive carbon containing adhesive and the carbon foam sections. Suitable heating rates may be highly dependent on the size and configuration of the enclosure and the characteristics of the heating device. In certain embodiments, heating rates of 1° C./min may be suitable. The maximum heating rate that can be used without degradation of the carbon foam EMI shield may be established by routine experimentation. Heating may be conducted in a non-reactive, oxygen free, or otherwise inert atmosphere. For similar reasons, care should also be taken when cooling the carbon foam sections and cured adhesive. In some embodiments, cooling may be conducted in a non-reactive, oxygen free, or otherwise inert atmosphere.

In some embodiments, once the carbon foam sections have been joined with the electrically conductive carbon containing adhesive, optional laminating layers may be applied to surfaces of the carbon foam sections. One or more layers of a laminating material may be laminated on surfaces of the carbon foam sections using standard laminating techniques for the given laminating material. Depending upon the laminating material, the laminating material may be applied to the carbon foam sections, for example, by dipping, spraying (including thermal spraying), lay-up methods, painting, gluing, mechanical fasteners, deposition (including chemical vapor deposition and vacuum deposition), and the like. The carbon foam of the carbon bonded shielding enclosure may also be impregnated with thermosetting or thermoplastic polymers, resins, ceramics, metals, and the like. As discussed previously, care should be taken to avoid creating defects, such as gaps and cracks. Such defects will reduce the EMI shielding effectiveness of the carbon foam EMI shield.

The carbon foam EMI shield may be used to at least partially shield personnel, electronic equipment, objects, materials, and the like, (herein referred to collectively as objects) from EMI. Such shielding is provided by positioning the object to be shielded in the at least partially enclosed volume defined by the enclosure walls, where those wall(s) are positioned between said objects and the source of the EMI.

The following examples are provided to illustrate particular features of certain embodiments of the carbon foam EMI shield. The invention is not limited by the particular configurations of the Examples.

### Example 1

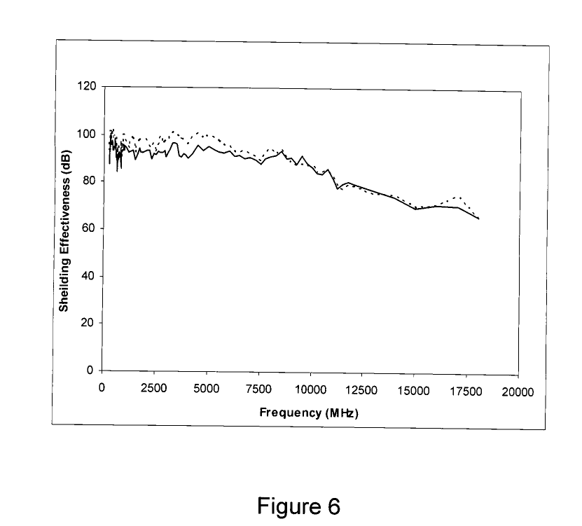

An adhesive was prepared from PRO-SET 125 Resin and PRO-SET 229 Hardener mixed with a weight ratio of 100 parts resin to 30 parts hardener. After combining the resin and hardener referenced above, 12% by weight of Pyrograf PR-19 LHT Low Density (LD) carbon nanofiber was mixed into the resin/hardener mixture. The adhesive mixture was used to join three (3) 24″×16″ CFOAM® 17 panels together to form a 24″×48″ panel that was tested for EMI Shielding Effectiveness (SE) in the frequency range of 400 MHz-18 GHz. As shown in FIG. 6, the adhesive showed an EMI shielding effectiveness of greater than 90 dB in the range of 400 MHz-8 GHz.

As a standard, a baseline test was performed to determine how much EMI signal can be received by an open test box. An aluminum plate was then placed over the box to determine the most that the test setup could actually shield. The difference in the results of these two measurements are shown in FIG. 6 and labeled DR (Dynamic Range). In the range of 400 MHz-8 GHz the aluminum plate achieved dB values above 90 dB.

### Example 2

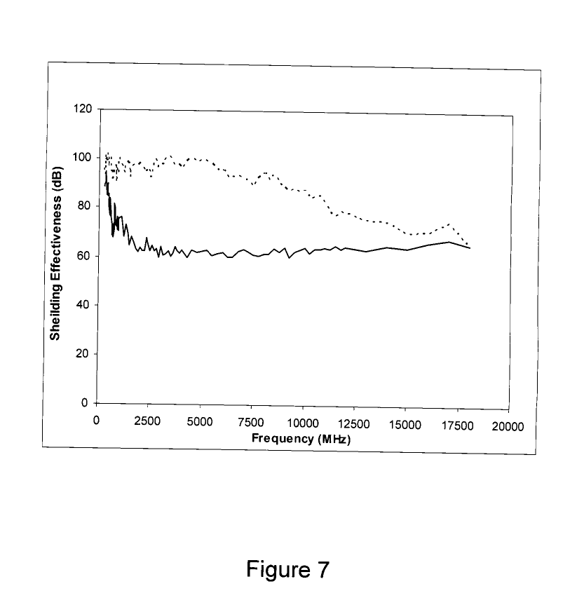

RSC-C2 is an EMI absorbing adhesive manufactured by Applied Poleramics and was tested for SE in the same manner as the adhesive in Example 1. The results of the RSC-C2 adhesive are shown in FIG. 7. In the range of 400 MHz-8 GHz, the dB values dropped rapidly from above 90 dB to just above 60 dB throughout most of the 400 MHz-18 GHz range.

### Example 3

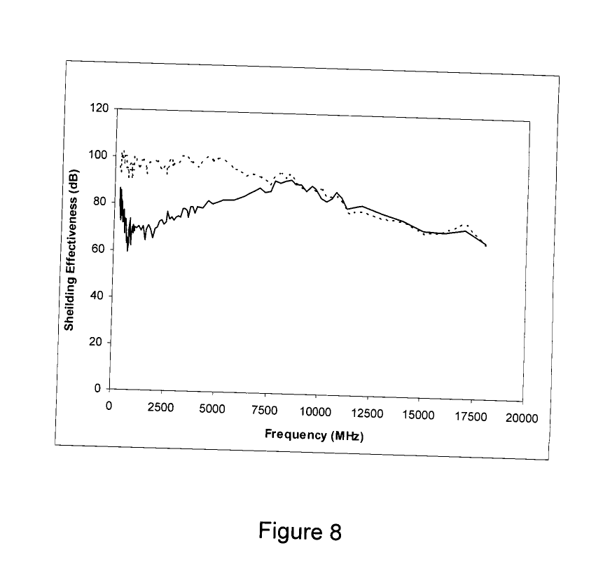

An adhesive manufactured by Aremco with the same carbon fiber used in the Aremco 551-RN was tested for SE. This is an ambient curing adhesive that is a two part epoxy with a loading of 50% by weight carbon fibers. This adhesive was tested for SE using the same procedure as the adhesive in Example 1 and the results are shown in FIG. 8. In the range of 400 MHz-8 GHz, the SE values in dB gradually increased from just above 60 dB at 400 MHz to just below 90 dB at 8 GHz.

### Example 4

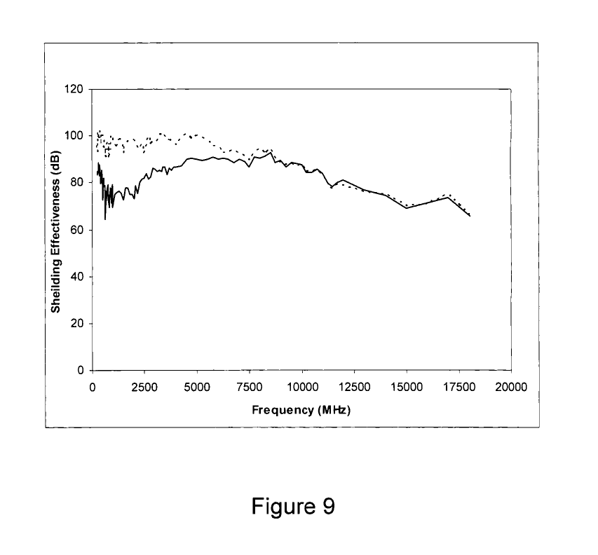

An adhesive manufactured by Aremco with the same carbon fiber used in the Aremco 551-RN was tested for SE. This is an ambient curing adhesive that is a two part epoxy with a loading of 60% by weight carbon fibers. This adhesive was tested for SE using the same procedure as the adhesive in Example 1 and the results are shown in FIG. 9. In the range of 400 MHz-8 GHz, the SE values gradually increase from just above 60 dB to just below 90 dB. This adhesive achieved a 90 dB value just above 4 GHz.

Various embodiments of the present invention have been discussed above in detail. The present invention has broad applicability to a wide variety of configurations that will be readily apparent to those skilled in the art. The invention is limited only by the appended claims.

What is claimed is:

1. An EMI shield comprising:
at least two sections of rigid porous electrically conductive carbon joined by an electrically conductive carbon containing adhesive to form an EMI shield, wherein said EMI shield has a shielding effectiveness of at least 40 dB between about 400 MHz and about 18 GHz.

2. The EMI shield of claim 1, wherein said EMI shield has a shielding effectiveness of at least about 60 dB between about 400 MHz and about 8 GHz.

3. The EMI shield of claim 1, wherein said EMI shield has a shielding effectiveness of at least about 80 dB between about 400 MHz and about 8 GHz.

4. The EMI shield of claim 1, wherein the electrically conductive carbon containing adhesive comprises from about 1% to about 75% by weight electrically conductive carbon in a polymer matrix.

5. The EMI shield of claim 1, wherein the electrically conductive carbon containing adhesive comprises from about 5% to about 60% by weight electrically conductive carbon in a polymer matrix.

6. The EMI shield of claim 1, wherein the electrically conductive carbon containing adhesive comprises from about 5% to about 20% by weight electrically conductive carbon in a polymer matrix.

7. The EMI shield of claim 1, wherein said electrically conductive carbon adhesive comprises epoxy.

8. The EMI shield of claim 1, wherein said electrically conductive carbon adhesive comprises a phenolic.

9. An EMI shield comprising:
at least two sections of electrically conductive carbon foam joined by an electrically conductive carbon containing adhesive to form an EMI shield, wherein said EMI shield has a shielding effectiveness of at least 40 dB between about 400 MHz and about 18 GHz.

10. The EMI shield of claim 9, wherein said EMI shield has a shielding effectiveness of at least about 60 dB between about 400 MHz and about 8 GHz.

11. The EMI shield of claim 9, wherein said EMI shield has a shielding effectiveness of at least about 80 dB between about 400 MHz and about 8 GHz.

12. An EMI shield comprising:
at least two sections of electrically conductive carbon foam joined by an electrically conductive carbon containing adhesive to form an EMI shield, wherein the electrically conductive carbon containing adhesive comprises electrically conductive carbon fibers in a polymer matrix, and wherein said EMI shield has a shielding effectiveness of at least 40 dB between about 400 MHz and about 18 GHz.

13. The EMI shield of claim 12, wherein said EMI shield has a shielding effectiveness of at least about 60 dB between about 400 MHz and about 8 GHz.

14. The EMI shield of claim 12, wherein said EMI shield has a shielding effectiveness of at least about 80 dB between about 400 MHz and about 8 GHz.
